(19) United States
(12) Patent Application Publication
(10) Pub. No.: US 2020/0335329 A1
(43) Pub. Date: Oct. 22, 2020

(54) ANNEALING PROCESSES TO STABILIZE NICKEL-CONTAINING FILMS

(71) Applicant: Applied Materials, Inc., Santa Clara, CA (US)

(72) Inventors: Jeffery W. Anthis, San Jose, CA (US); Nicolas Louis Gabriel Breil, Alviso, CA (US); David Thompson, San Jose, CA (US); Feng Q. Liu, San Jose, CA (US); Liqi Wu, San Jose, CA (US)

(73) Assignee: Applied Materials, Inc., Santa Clara, CA (US)

(21) Appl. No.: 16/388,543

(22) Filed: Apr. 18, 2019

(51) Int. Cl. H01L 21/02

(52) U.S. Cl. CPC H01L 21/02175; H01L 45/146; H01L 21/02255; H01L 21/02205

(57) ABSTRACT

Exemplary methods of forming nickel-containing materials may include forming a layer of a nickel-and-oxygen-containing material overlying a substrate. The nickel-and-oxygen-containing material may be characterized by a carbon content. The methods may also include annealing the nickel-containing material with a carbon-containing precursor at a temperature greater than or about 100° C. The carbon content within the nickel-and-oxygen-containing material may be maintained during the annealing.

### TECHNICAL FIELD

The present technology relates to semiconductor processes and equipment. More specifically, the present technology relates to treating nickel-containing materials.

### BACKGROUND

Integrated circuits are made possible by processes which produce intricately patterned material layers on substrate surfaces. Producing patterned material on a substrate requires controlled methods for deposition and removal of materials. However, with new device designs, producing high quality layers of material includes new challenges.

Thus, there is a need for improved systems and methods that can be used to produce high quality devices and structures. These and other needs are addressed by the present technology.

### SUMMARY

Exemplary methods of forming nickel-containing materials may include forming a layer of a nickel-and-oxygen-containing material overlying a substrate. The nickel-and-oxygen-containing material may be characterized by a carbon content. The methods may also include annealing the nickel-containing material with a carbon-containing precursor at a temperature greater than or about 100° C. The carbon content within the nickel-and-oxygen-containing material may be maintained during the annealing.

In some embodiments, the substrate may be or include at least one of platinum, titanium, a dielectric material including silicon oxide, or tantalum. The carbon-containing precursor may be or include carbon dioxide or carbon monoxide. The annealing may be performed at a temperature greater than or about 300° C. The method may also include forming a conductive material overlying the nickel-and-oxygen-containing material. The conductive material may be or include at least one of platinum, titanium nitride, or tantalum nitride. The forming may be performed at a pressure less than or about 20 Torr. The annealing may be performed at a pressure greater than or about 20 Torr, and may be performed at a pressure greater than or about 1,000 Torr. The nickel-and-oxygen-containing material may be characterized by a carbon content greater than 0 atomic % and up to about 20 atomic %.

The present technology may also encompass methods of forming a nickel-containing material. The methods may include forming a layer of a nickel-and-oxygen-containing material overlying a substrate. The nickel-and-oxygen-containing material may be characterized by a carbon content greater than or about 0.1 atomic %. The methods may include subsequently transferring the substrate to a second processing chamber. The methods may also include annealing the nickel-containing material with a carbon-containing precursor at a temperature greater than or about 100° C. The carbon content may be maintained greater than or about 0.1 atomic % during the annealing.

In some embodiments, the methods may also include annealing the nickel-containing material with a nitrogen-containing precursor at a temperature greater than or about 100° C. The carbon content may be maintained greater than or about 0.1 atomic % during the annealing with the nitrogen-containing precursor. The nickel-and-oxygen-containing material may be characterized by a carbon content greater than 0.1 atomic % and up to about 20 atomic %. The annealing may be performed at a temperature greater than or about 300° C. The forming may be performed at a pressure below or about 20 Torr. The substrate may be maintained under vacuum while being transferred to the second processing chamber. After receiving the substrate, the second processing chamber may be pressurized to above or about 300 Torr. The annealing may be performed above or about 300 Torr. The carbon-containing precursor may be or include carbon dioxide or carbon monoxide.

The present technology may also encompass methods of forming a nickel-containing material. The methods may include forming a layer of a nickel-and-oxygen-containing material overlying a substrate. The nickel-and-oxygen-containing material may be characterized by a carbon content greater than or about 1 atomic %. The methods may also include annealing the nickel-containing material with carbon monoxide or carbon dioxide at a temperature greater than or about 300° C. The carbon content may be maintained greater than or about 1 atomic % during the annealing. The methods may also include forming a conductive material overlying the nickel-and-oxygen-containing material. The conductive material may be or include at least one of platinum, titanium nitride, or tantalum nitride. In some embodiments, the nickel-and-oxygen-containing material may be characterized by a carbon content greater than 1 atomic % and up to about 20 atomic %. The methods may also include annealing the conductive material at a temperature above or about 400° C. The carbon content of the nickel-and-oxygen-containing material may be maintained greater than 1 atomic % during the annealing of the conductive material.

Such technology may provide numerous benefits over conventional systems and techniques. For example, the processes may produce materials capable of maintaining a carbon content subsequent further processing. Additionally, the processes may afford improved consistency of a nickel-containing layer as deposited. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of one embodiment of an exemplary processing system according to some embodiments of the present technology.

FIG. 2 shows exemplary operations in a method of formation and treating according to some embodiments of the present technology.

FIGS. 3A-3D show cross-sectional views of substrates being processed according to some embodiments of the present technology.

FIG. 4 shows exemplary operations in a method of formation and treating according to some embodiments of the present technology.

Several of the figures are included as schematics. It is to be understood that the figures are for illustrative purposes, and are not to be considered of scale or proportion unless specifically stated to be of scale or proportion. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

As devices produced in semiconductor processing continue to shrink, uniformity, material quality, process control, and repeatability are becoming more challenging from process to process. To continue to improve device performance at reduced scale, alternative films and processes are being investigated for additional performance improvements relative to conventional devices.

For example, conventional memory structures include particular limitations. Dynamic random-access memory is a structure that, although characterized by relatively beneficial speed, is volatile. Accordingly, the memory tends to lose data when system power is off. Flash memory does not suffer from this loss, and maintains data throughout power cycling, however, the process of reading and writing is performed in multiple cycles, which may be a slower process. Accordingly, improved memory structures are being developed with a variety of newer material layers. For example, conductive bridging RAM, oxide RAM, magnetic RAM, correlated electron RAM, resistive RAM, and other memory structures are being developed. Many of these structures include new material layers utilizing transition metals or metalloids, which may boost operational characteristics of produced cells.

In general, a dielectric material in metal-insulator-metal or resistive memory structures is switched between a high resistance state and a lower resistance state by application of a voltage across the metal electrodes. By applying a voltage, such as a set voltage, a conductive path may be formed through the dielectric material that can be homogenous or localized. This path may be due to a phase change, formation of a filament, electroformation, or metal-insulator transition, which may allow the materials to operate as one or both of a memory or switch. By breaking the conduction path, such as with a reset, the material may revert to the higher resistance state. Some conventional attempts at developing these non-volatile switches have used titanium oxide, tantalum oxide, and other dielectrics as this resistive layer, however these materials have less desirable characteristics despite more facile formation, and thus some technologies are switching to alternative materials like nickel oxide. Nickel may have a higher work function than titanium, so titanium oxide may be characterized by a much higher affinity to oxygen, and thus the material may be less effective in transition devices relative to nickel oxide. However, nickel oxide may be characterized by relatively unpredictable switching operations in application, where set/reset voltages may be higher or unpredictable, and switching operations may lead to premature failures compared to some conventional dielectric oxides.

Nickel oxide and nickel oxycarbide are types of material that may be incorporated in memory structures in one or more ways. For example, the material may be included as a switching medium between two electrodes in a resistive memory structure. However, conventional attempts at producing functioning materials have struggled with fabricating high-quality nickel oxide due to both film formation as well as film performance issues. For example, between issues with deposition and operation, localized conduction paths or filaments may be more likely to form in nickel oxide, which may cause damage to the switching layer itself, and increase the likelihood of catastrophic breakdown of the dielectric material. Electroformation processes during which voltage may induce damage to the layer to facilitate operation as a switching layer, may also be more difficult to control with nickel oxide, which can over-damage the layer. These effects reduce the predictability of the switching, as well as reduce the viability of nickel oxide in the memory devices.

Additionally, carbon incorporation in nickel oxide films may contribute to driving a correlated electron effect in correlated electron RAM. However, carbon incorporated into nickel oxide films may be lost in later processing, as the carbon within the film may be less thermodynamically favorable than when released as gas. For example, an Ellingham diagram of carbon incorporation with nickel oxide plotted against carbon monoxide illustrates that incorporation within the nickel oxide material may become less thermodynamically favorable as temperature increases. This bears out in experiments that have shown that as integration continues with devices incorporating carbon in nickel oxide, when higher temperature operations are performed, out gassing can occur to the point of device destruction or failure. Additionally, densifying anneals on the nickel oxycarbide films performed with inert gas alone can cause almost complete removal of carbon content within the film. Consequently, many conventional technologies cannot maintain carbon incorporation within nickel oxide films.

The present technology overcomes these issues by performing a particular anneal subsequent formation of the nickel oxycarbide material. The anneal may be performed with a carbon-containing precursor which may facilitate reversing a decomposition reaction while densifying the material layer. As a more kinetically stable film may be produced with this anneal, a larger thermodynamic barrier may exist relative to the decomposition and outgassing of carbon, which may reduce carbon loss overall, as well as facilitate maintaining carbon incorporation during later integration operations.

Although the remaining disclosure will routinely identify specific structures, such as memory, for which the present structures and methods may be employed, it will be readily understood that the systems and methods are equally applicable to any number of structures and devices that may benefit from the incorporation of nickel oxide films. Accordingly, the technology should not be considered to be so limited as for use with any particular structures alone. Moreover, although an exemplary tool system will be described to provide foundation for the present technology, it is to be understood that the present technology can be produced in any number of semiconductor processing chambers and tools that may perform some or all of the operations to be described.

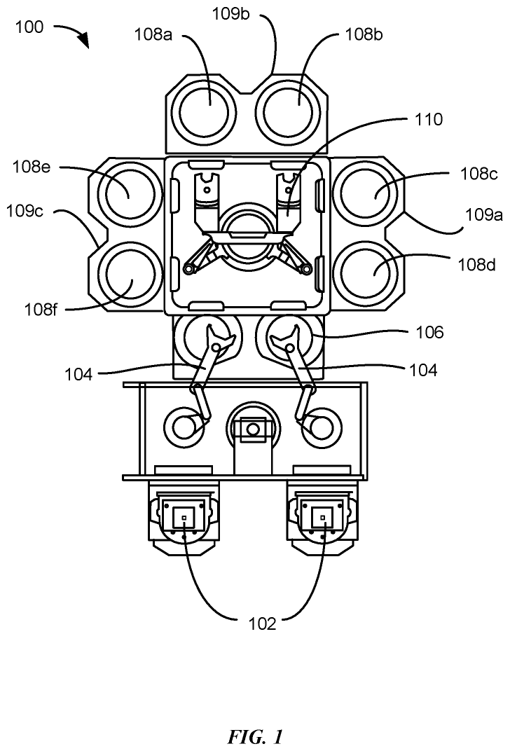

FIG. 1 shows a top plan view of one embodiment of a processing system 100 of deposition, etching, baking, and curing chambers according to some embodiments of the present technology. In the figure, a pair of front-opening unified pods (FOUPs) 102 supply substrates of a variety of sizes that are received by robotic arms 104 and placed into a low pressure holding area 106 before being placed into one of the substrate processing chambers 108a-f, positioned in tandem sections 109a-c. Although a tandem system is illustrated, it is to be understood that platforms incorporating standalone chambers are equally encompassed by the present technology. A second robotic arm 110 may be used to transport the substrate wafers from the holding area 106 to the substrate processing chambers 108a-f and back. Each substrate processing chamber 108a-f, can be outfitted to perform a number of substrate processing operations including any number of deposition processes including cyclical layer deposition (CLD), atomic layer deposition (ALD), chemical vapor deposition (CVD), physical vapor deposition (PVD), as well as etch, pre-clean, anneal, plasma processing, degas, orientation, and other substrate processes.

The substrate processing chambers 108a-f may include one or more system components for depositing, annealing, curing and/or etching a material film on the substrate or wafer. In one configuration, two pairs of the processing chambers, e.g., 108c-d and 108e-f, may be used to deposit material on the substrate, and the third pair of processing chambers, e.g., 108a-b, may be used to cure, anneal, or treat the deposited films. In another configuration, all three pairs of chambers, e.g., 108a-f, may be configured to both deposit and cure a film on the substrate. Any one or more of the processes described may be carried out in additional chambers separated from the fabrication system shown in different embodiments. It will be appreciated that additional configurations of deposition, etching, annealing, and curing chambers for material films are contemplated by system 100. Additionally, any number of other processing systems may be utilized with the present technology, which may incorporate chambers for performing any of the specific operations. In some embodiments, chamber systems which may provide access to multiple processing chambers while maintaining a vacuum environment in various sections, such as the noted holding and transfer areas, may allow operations to be performed in multiple chambers while maintaining a particular vacuum environment between discrete processes.

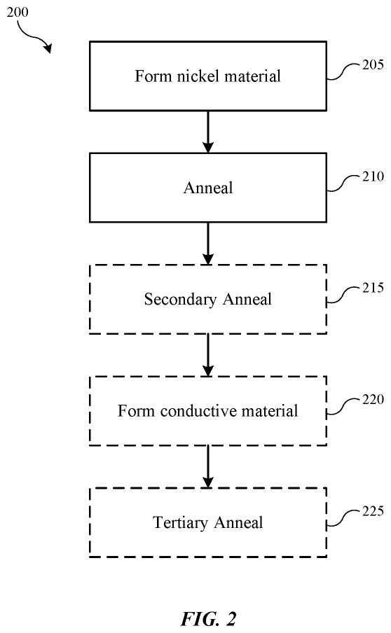

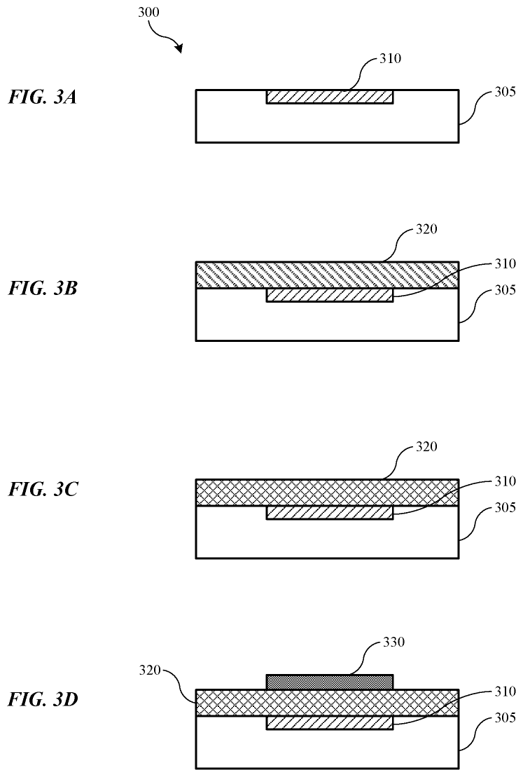

System 100, or more specifically chambers incorporated into system 100 or other processing systems, may be used to produce structures according to some embodiments of the present technology. FIG. 2 shows exemplary operations in a method 200 of forming and treating a semiconductor device according to some embodiments of the present technology. Method 200 may be performed in one or more processing chambers, such as chambers incorporated in system 100, for example. Method 200 may or may not include one or more operations prior to the initiation of the method, including front-end processing, deposition, etching, polishing, cleaning, or any other operations that may be performed prior to the described operations. The method may include a number of optional operations as denoted in the figure, which may or may not be specifically associated with some embodiments of methods according to the present technology. Method 200 describes operations shown schematically in FIGS. 3A-3C, the illustrations of which will be described in conjunction with the operations of method 200. It is to be understood that FIG. 3 illustrates only partial schematic views with limited details, and in some embodiments a substrate may contain any number of transistor or semiconductor sections having aspects as illustrated in the figures, as well as alternative structural aspects that may still benefit from any of the aspects of the present technology.

Method 200 may involve optional operations to develop the semiconductor structure to a particular fabrication operation. Although in some embodiments method 200 may be performed on a base structure, in some embodiments the method may be performed subsequent transistor or other material formation. As illustrated in FIG. 3A, the semiconductor structure may represent a device 300 after front-end or other processing has been completed. For example, substrate 305 may be a planar material, or may be a structured device, which may include multiple materials configured as posts, trenches, or other structures as would be understood are similarly encompassed by the present technology. Substrate 305 may include any number of conductive and/or dielectric materials including metals, which may include transition metals, post-transition metals, metalloids, oxides, nitrides, and carbides of any of these materials, as well as any other materials that may be incorporated within a structure.

One or more material layers may be formed over some or all of substrate 305, as well as formed at least partially within the substrate, to produce a structure that may be a planarized conductive material within a dielectric material in embodiments. For example, in some embodiments a conductive material 310 may optionally be formed overlying substrate 305, or recessed within a portion of substrate material 305. As one non-limiting example, at the exposed surface of substrate 305 may be a dielectric material, such as silicon oxide or any other dielectric, in which the conductive material may be formed. The conductive material 310 may be a continuous layer across the substrate, or may be intermittently formed across the surface of the substrate as illustrated. In one non-limiting example, the conductive material may be or include a metal that may be formed intermittently across the substrate 305. The metal may include tantalum, praseodymium, hafnium, titanium, iridium, rhodium, platinum, or any other material that may operate as an electrode in a memory structure or may be present in alternative structures, for example, and may include a combination of materials as well as oxides or nitrides of any of these materials in some embodiments.

The conductive material 310 may be etched, planarized, or otherwise processed to produce an intermittent pattern in some embodiments, which either through etching or other formation may expose a portion of substrate 305 between segments of conductive material 310. Although illustrated as a single instance, it is to be understood that any number of sections of conductive material 310 may be included. Additionally, although schematically illustrated as including straight sidewalls, the formation or removal process of conductive material 310 may produce angled sidewalls. Thus, in some embodiments, the segments of conductive material 310 may be characterized by a frustum shape, or by an angled surface along one or more faces of the segments. Substrate 305, which may include conductive material 310, may be housed or positioned in a processing region of a semiconductor processing chamber, and method 200 may be performed to form a semiconductor material on the substrate.

Method 200 may include forming a layer of a nickel-containing material overlying the substrate and conductive material 310 in operation 205. The nickel-containing material may be a nickel-containing dielectric in some embodiments, such as a nickel-and-oxygen-containing material, which can operate as a switching layer, for example, between electrodes of a memory device. The nickel-containing material may be formed across the conductive material 310, as illustrated in FIG. 3B with nickel-and-oxygen-containing material 320, and may extend fully across the material to overlie both regions of conductive material 310 as well as substrate material 305.

The nickel or nickel-and-oxygen-containing film may be formed by any number of deposition techniques including chemical vapor deposition, physical vapor deposition, or atomic layer deposition. However, forming nickel oxide layers with conventional chemical vapor deposition may produce lower quality films in some embodiments. For example, the film produced may be less stable, which may cause uniformity issues during subsequent operations. For example, outgassing during subsequent processes may increase porosity in the film, which may reduce planarity or material properties of the film produced. Consequently, when an additional electrode is formed overlying the material to produce a memory structure, for example, device performance may be compromised. Cyclically formed films may be characterized by increased density, and may produce more stable films.

A variety of materials may be used for the nickel-containing precursors and the oxygen-containing precursors. Exemplary oxygen-containing precursors may be or include any oxygen-containing precursor. For example, the oxygen-containing precursor may be or include water, diatomic oxygen, ozone, oxygen plasma, a hydroxyl-containing precursor or alcohol, nitrogen-and-oxygen-containing precursors, or any other material including oxygen that may be incorporated with nickel to produce a nickel oxide material.

Exemplary nickel-containing precursors may include any nickel-containing precursor, and in some embodiments may include one or more nickel-containing hydrocarbons or organonickel compounds, such as precursors characterized by one or more nickel-carbon bonds. For example, nickel-containing precursors may be or include nickel alkene complexes, nickel allyl complexes including halide-containing precursors, nickelocene, nickel carbene complexes, or other materials that may include nickel and one or more of hydrogen, carbon, nitrogen, and/or oxygen. Exemplary formulae for nickel-containing precursors may include (R₅C₅)2Ni, where R may be H or any alkyl group, and nickel-containing alkoxides, which may include as examples only, bis(ethylcyclopentadienyl)nickel, bis(cyclopentadienyl)nickel, bis(methylcyclopentadienyl)nickel, bis(pentamethylcyclopentadienyl)nickel, allyl(cyclopentadienyl)nickel, bis(triphenylphosphone)nickel dichloride, or nickel bis(2,2,6,6-tetramethyl-3,5-heptanedioate). Exemplary nickel-containing precursors may be provided in gaseous form, although liquid and solid precursors may also be used in some embodiments.

As previously discussed, an amount of carbon may be incorporated within the film using many of the noted precursors to produce a nickel oxycarbide film in some embodiments, which may adjust or tune electrical properties within the nickel oxide film. The present technology may include an atomic percentage of carbon within the first layer that may be consistent through the depth of the layer, or may be incorporated along a gradient with higher concentration close to the material surface, and reduced incorporation through the film depth. The carbon percentage may be the same or different throughout the layer, and may include a carbon content between about 0 atomic % and about 50 atomic %. In some embodiments, the layer may include a carbon content between or about 0 atomic % and about 40 atomic %, between or about 0 atomic % and about 30 atomic %, between or about 0 atomic % and about 20 atomic %, between or about 0 atomic % and about 10 atomic %, greater than or about 0 atomic %, greater than or about 0.1 atomic %, greater than or about 0.2 atomic %, greater than or about 0.3 atomic %, greater than or about 0.5 atomic %, greater than or about 0.8 atomic %, greater than or about 1 atomic %, greater than or about 3 atomic %, greater than or about 5 atomic %, greater than or about 8 atomic %, greater than or about 10 atomic %, or any other amount or range encompassed by any of these ranges.

Process conditions may also be configured to affect the formation. In some embodiments, some aspects of the methods may be performed under vacuum, and in some embodiments vacuum conditions may not be broken as a substrate is transferred between chambers to perform operations of the methods. Pressure within the system may be maintained at less than or about 100 Torr for any of the formation operations being performed, and in some embodiments may be maintained at less than or about 80 Torr, less than or about 60 Torr, less than or about 50 Torr, less than or about 40 Torr, less than or about 30 Torr, less than or about 20 Torr, less than or about 10 Torr, less than or about 5 Torr, less than or about 1 Torr, less than or about 0.1 Torr, less than or about 0.01 Torr, or less, although formation rates may increase as pressure is maintained or increased between about 0.5 Torr and about 50 Torr in some embodiments.

Temperature may also impact formation of the nickel-containing layers, and in some embodiments a temperature of any of the operations, either individually or collectively, may be performed at temperatures above or about 100° C. One or more operations may also be performed at temperatures above or about 150° C., and may be performed at temperatures above or about 200° C., above or about 250° C., above or about 300° C., above or about 350° C., above or about 400° C., above or about 450° C., above or about 500° C., or higher. The operational temperatures may be adjusted based on precursors used, for example, as well as on device thermal budgets. For example, in some embodiments a nickel-containing film may be produced as a mid or back-end-of-line operation for which temperature may be maintained below or about 500° C., or lower. Additionally, some precursors may begin to thermally decompose above certain temperatures, and thus operational temperatures may be adjusted to reduce precursor decomposition in some embodiments.

The nickel oxide material may be formed to any thickness to produce a target overall structural thickness. For example, the combined thickness for all incorporated layers may be greater than or about 1 nm, greater than or about 10 nm, greater than or about 50 nm, greater than or about 100 nm, greater than or about 500 nm, or more, as well as any smaller range encompassed by any of these stated ranges. Any constituent layer may occupy any amount of the overall thickness of the layer. In some embodiments the nickel oxide material may be formed to a lesser amount than may be used in some conventional technologies. Accordingly, in some embodiments the nickel oxide layer may be less than or about 100 nm, and may be less than or about 50 nm, less than or about 40 nm, less than or about 30 nm, less than or about 20 nm, less than or about 10 nm, less than or about 9 nm, less than or about 8 nm, less than or about 7 nm, less than or about 6 nm, less than or about 5 nm, less than or about 4 nm, less than or about 3 nm, less than or about 2 nm, less than or about 1 nm, or less.

After the nickel-and-oxygen-containing material has been formed, an anneal operation may be performed to densify or stabilize the film. As noted previously, many conventional anneals will cause the incorporated carbon of the film to outgas, as anneal processes often occur at increased temperatures, which may drive the carbon to a more stable gaseous form. However, the present technology utilizes a carbon-containing precursor to perform the anneal, which may stabilize the film while maintaining the carbon content. For example, a carbon-containing or carbon-and-oxygen-containing precursor may be flowed into a processing chamber housing a substrate having a nickel oxycarbide film at operation 210. The precursor may be used to perform an anneal to stabilize the nickel oxycarbide film, while additionally maintaining the incorporation of carbon within the film, by maintaining or increasing kinetic stability of incorporation as opposed to outgassing. For example, the decomposition of nickel oxycarbide may occur by the general formula:

NiOC→Ni+COₓ+NiO

By utilizing a carbon-containing or carbon-and-oxygen-containing precursor, the process may drive the equation towards the left while densifying the material into a state that may be more kinetically stable with respect to decomposition in terms of carbon loss, which is illustrated in FIG. 3C by the adjusted contrast of the nickel-and-oxygen-containing material 320 illustrating a more stable film after anneals according to the present technology. This more stable film may further provide or enhance a kinetic barrier to decomposition, which may facilitate carbon maintenance during later operations, which may occur at temperatures that may otherwise favor decomposition and outgassing of carbon.

The carbon-containing or carbon-and-oxygen-containing precursor may include any precursor incorporating carbon or both carbon and oxygen. As two non-limiting examples, carbon monoxide and carbon dioxide may be used in anneals according to the present technology. As these precursors may be direct products of the decomposition reaction of nickel oxycarbide, they may facilitate maintaining the incorporation within the film by driving the process to the left of the equation. Pressure and temperature may impact the process, and thus in some embodiments the pressure and/or the temperature may be adjusted from the conditions at which formation occurred. For example, increasing the pressure during the carbon-and-oxygen-containing precursor anneal has been shown to increase carbon incorporation through the film. For example, at constant temperature, a film annealed at 380 Torr maintained almost 5% less carbon than a similar film annealed at 760 Torr over a similar time period. Accordingly, anneals according to the present technology may be performed at pressures greater than or about 20 Torr, and in some embodiments may be performed at pressures greater than or about 50 Torr, greater than or about 100 Torr, greater than or about 200 Torr, greater than or about 300 Torr, greater than or about 500 Torr, greater than or about 760 Torr, greater than or about 1,000 Torr, greater than or about 1,200 Torr, greater than or about 1,400 Torr, greater than or about 1,500 Torr, greater than or about 1,600 Torr, greater than or about 1,800 Torr, greater than or about 2,000 Torr, or higher. In some embodiments, depending on certain process conditions, as pressure reduces below 760 or 380 Torr, the anneal may become incapable of maintaining the carbon content within the nickel oxycarbide during the anneal, or during later fabrication processes.

Temperature may also contribute to the anneal, and in some embodiments the anneal may be performed at temperatures between about 100° C. and about 500° C., and may occur at temperatures greater than or about 100° C., greater than or about 200° C., greater than or about 300° C., greater than or about 350° C., greater than or about 400° C., greater than or about 450° C., greater than or about 500° C., greater than or about 550° C., or greater. The temperature may also be adjusted relative to the pressure at which the anneal may be performed. For example, when process pressures during the anneal are below about 1,000 Torr, the temperature at which the anneal may be performed may be maintained below or about 500° C. When temperatures exceed this threshold in this pressure regime, the anneal may retain less carbon than when the temperature and pressure are coordinated.

Subsequent a carbon-containing or carbon-and-oxygen-containing precursor anneal, a subsequent anneal may be performed at optional operation 215. For example, an inert gas, such as helium, nitrogen, or argon, may be delivered to the substrate to further anneal the film at any of the temperatures and/or pressures noted above. Without the carbon-and-oxygen-containing precursor anneal, a nitrogen anneal performed above 300° C. was shown to fully remove the carbon content from a nickel oxycarbide film. However, when a carbon-and-oxygen-containing precursor anneal was performed according to the present technology, a subsequent nitrogen anneal had limited effect on the carbon content in the nickel oxycarbide film.

The present technology may also produce combination structures that may include additional materials, as well as additional layers. FIG. 3D may also illustrate a cross-sectional view of substrates being processed according to additional embodiments of the present technology in which additional structural layers may be included. FIG. 3D illustrates additional embodiments in which a subsequent conductive material 330 may be formed overlying the nickel oxide layer 320. The subsequent layer of conductive material 330 may be incorporated on an opposite surface of the nickel oxide or nickel oxycarbide material as the first conductive material 310. For example, in an optional operation 220, subsequent formation of the nickel-and-oxygen-containing material, additional electrode material 330 may be formed over the nickel-and-oxygen-containing material 320. The formation of an additional electrode material may produce a memory device where the nickel oxycarbide material may operate as a switching layer. The conductive material 330 may be any of the electrode materials previously noted, as well as any other conductive materials that may operate as an electrode of the formed structure. The conductive material 330 may be the same electrode material as conductive material 310, although in some embodiments the materials may be different from one another.

In some embodiments an additional anneal, such as a tertiary anneal, may be performed at optional operation 225. The tertiary anneal may be performed further down a fabrication sequence, such as in an integration operation. This anneal may be performed on conductive material 330 or any other material, and the anneal may be performed at temperatures exceeding 300° C. In conventional operations without a carbon-and-oxygen-containing precursor anneal according to embodiments of the present technology, these types of tertiary anneals would often cause outgassing from the underlying film, which could destroy the structure. However, when a carbon-and-oxygen-containing precursor anneal was performed according to the present technology, a subsequent tertiary anneal did not further reduce the carbon content in the nickel oxycarbide film.

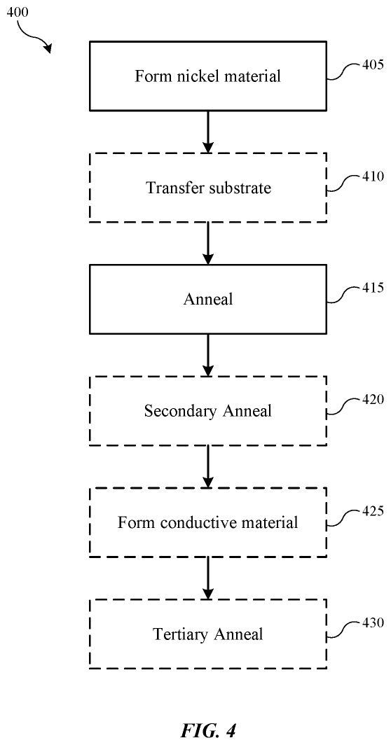

Although the present methods may be performed in processing chambers configured to perform multiple operations, methods according to some embodiments of the present technology may include transferring a substrate from a deposition chamber in which a nickel-and-oxygen-containing film may be formed to a chamber in which a carbon-containing or carbon-and-oxygen-containing precursor anneal may be performed. FIG. 4 shows exemplary operations in a method 400 of formation according to some embodiments of the present technology. In some embodiments method 400 may be similar to method 200 described above, and may include any of the operations, processing conditions, or produced film characteristics described above. Method 400 may encompass aspects of method 200 as well as incorporating additional operations.

Method 400 may optionally include forming an electrode material on or recessed in a substrate material as described above. Method 400 may include forming a nickel-containing material, such as a nickel-and-oxygen-containing material, adjacent the electrode material at operation 405. The nickel-and-oxygen-containing material may incorporate an amount of carbon as previously described. Subsequent the formation, the present technology may include transferring the substrate from a first processing chamber in which the formation occurred at optional operation 410. The substrate may be transferred to a second processing chamber in which an anneal may be performed. After the substrate has been transferred, an anneal may be performed with a carbon-containing or carbon-and-oxygen-containing precursor at operation 415. The anneal may be performed at any of the conditions as described previously.

In some embodiments in which a substrate is transferred between operations, a pressure within the system may be adjusted. For example, in some embodiments the formation operation may be performed at a first pressure. Transfer between chambers may occur at a second pressure, and an anneal may be performed at a third pressure greater than each of the first pressure and the second pressure. Any of these pressures may be any of the pressures, or within any of the pressure ranges, noted elsewhere. Depending on the system and the formation pressure, the formation may occur at a temperature above a pressure within a mainframe or cluster tool. Accordingly, in some embodiments the pressure may be raised to the first pressure within a first processing chamber, and then the formation process may be performed. Subsequently, the pressure may be reduced to the second pressure and the substrate may be removed from the first processing chamber, and transferred to a second processing chamber. In some embodiments, this transfer may all occur at the same pressure, which may be the second pressure. Once secured in the second processing chamber, the chamber may be pressurized to the third pressure, which may be above 100 Torr, above 1,000 Torr, or higher as noted previously. Accordingly, the pressure may be regulated in each operation to perform the process within the pressure ranges noted above, which may improve carbon retention in nickel oxycarbide films.

An additional secondary anneal may be performed at optional operation 420, which may be similar to the inert anneal described previously. After one or both of these anneals, subsequent processing may be performed. For example, an electrode may be formed adjacent or overlying the nickel oxycarbide film in optional operation 425, and which may include any of the materials or processes described above. A tertiary anneal similar to a tertiary anneal performed at operation 225 may be performed subsequent any of these operations at optional operation 430.

Accordingly, embodiments of the present technology may incorporate a carbon-containing or a carbon-and-oxygen-containing precursor anneal during fabrication operations incorporating a nickel oxide film. The anneal may improve the characteristics of the nickel oxide film, and maintain a carbon incorporation that may be equal to or exceed the as-deposited carbon incorporation amount. This carbon retention may lead to improved performance of the nickel oxide film, such as by improving switching or power consumption relative to conventional materials.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursors, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A method of forming a nickel-containing material, the method comprising:
forming a layer of a nickel-and-oxygen-containing material overlying a substrate, wherein the nickel-and-oxygen-containing material is characterized by a carbon content; and
annealing the nickel-containing material with a carbon-containing precursor at a temperature greater than or about 100° C., wherein the carbon content is maintained during the annealing.

2. The method of forming a nickel-containing material of claim 1, wherein the substrate comprises at least one of platinum, titanium, a dielectric, or tantalum.

3. The method of forming a nickel-containing material of claim 1, wherein the carbon-containing precursor comprises carbon dioxide or carbon monoxide.

4. The method of forming a semiconductor device of claim 1, wherein the annealing is performed at a temperature greater than or about 300° C.

5. The method of forming a nickel-containing material of claim 1, further comprising forming a conductive material overlying the nickel-and-oxygen-containing material, wherein the conductive material comprises at least one of platinum, titanium nitride, or tantalum nitride.

6. The method of forming a nickel-containing material of claim 1, wherein the forming is performed at a pressure less than or about 20 Torr.

7. The method of forming a nickel-containing material of claim 1, wherein the annealing is performed at a pressure greater than or about 20 Torr.

8. The method of forming a nickel-containing material of claim 7, wherein the annealing is performed at a pressure greater than or about 1,000 Torr.

9. The method of forming a nickel-containing material of claim 1, wherein the nickel-and-oxygen-containing material is characterized by a carbon content greater than 0 atomic % and up to about 20 atomic %.

10. A method of forming a nickel-containing material, the method comprising:
forming a layer of a nickel-and-oxygen-containing material overlying a substrate, wherein the nickel-and-oxygen-containing material is characterized by a carbon content greater than or about 0.1 atomic %;
subsequently transferring the substrate to a second processing chamber; and
annealing the nickel-containing material with a carbon-containing precursor at a temperature greater than or about 100° C., wherein the carbon content is maintained greater than or about 0.1 atomic % during the annealing.

11. The method of forming a nickel-containing material of claim 10, further comprising annealing the nickel-containing material with a nitrogen-containing precursor at a temperature greater than or about 100° C., wherein the carbon content is maintained greater than or about 0.1 atomic % during the annealing with the nitrogen-containing precursor.

12. The method of forming a nickel-containing material of claim 10, wherein the nickel-and-oxygen-containing material is characterized by a carbon content greater than 0.1 atomic % and up to about 20 atomic %.

13. The method of forming a nickel-containing material of claim 10, wherein the annealing is performed at a temperature greater than or about 300° C.

14. The method of forming a nickel-containing material of claim 10, wherein the forming is performed at a pressure below or about 20 Torr.

15. The method of forming a nickel-containing material of claim 14, wherein the substrate is maintained under vacuum while being transferred to the second processing chamber.

16. The method of forming a nickel-containing material of claim 15, wherein, after receiving the substrate, the second processing chamber is pressurized to above or about 300 Torr, and wherein the annealing is performed above or about 300 Torr.

17. The method of forming a nickel-containing material of claim 10, wherein the carbon-containing precursor comprises carbon dioxide or carbon monoxide.

18. A method of forming a nickel-containing material, the method comprising:
forming a layer of a nickel-and-oxygen-containing material overlying a substrate, wherein the nickel-and-oxygen-containing material is characterized by a carbon content greater than or about 1 atomic %;
annealing the nickel-containing material with carbon monoxide or carbon dioxide at a temperature greater than or about 300° C., wherein the carbon content is maintained greater than or about 1 atomic % during the annealing; and
forming a conductive material overlying the nickel-and-oxygen-containing material, wherein the conductive material comprises at least one of platinum, titanium nitride, or tantalum nitride.

19. The method of forming a memory device of claim 18, wherein the nickel-and-oxygen-containing material is characterized by a carbon content greater than 1 atomic % and up to about 20 atomic %.

20. The method of forming a memory device of claim 18, further comprising annealing the conductive material at a temperature above or about 400° C., wherein the carbon content of the nickel-and-oxygen-containing material is maintained greater than 1 atomic % during the annealing of the conductive material.
